(19) United States
(12) Patent Application Publication
(10) Pub. No.: US 2023/0304752 A1
(43) Pub. Date: Sep. 28, 2023

(54) UNIVERSAL MOUNTING MECHANISM

(71) Applicant: Cooler Master Co., Ltd., Taipei City (TW)

(72) Inventors: Bo-zhang Chen, Taipei City (TW); Jen-chih Cheng, Taipei City (TW)

(21) Appl. No.: 18/112,482

(22) Filed: Feb. 21, 2023

(30) Foreign Application Priority Data
Mar. 22, 2022 (CN) 202210285920.7

(51) Int. Cl. F28F 99/00; H05K 7/20

(52) U.S. Cl. CPC F28F 99/00; H05K 7/20272; F28F 2275/08

(57) ABSTRACT

A universal mounting mechanism including a mounting bracket configured to mount a liquid-cooling heat exchange apparatus to a substrate or an electronic component and at least one universal fastener assembly is provided. The at least one universal fastener assembly is orthogonally assembled through the mounting bracket. The liquid-cooling heat exchange apparatus includes a first liquid-cooling heat exchange apparatus having a first waterblock set or a second liquid-cooling heat exchange apparatus having a second waterblock set. The first waterblock set has a first block thickness, and the second waterblock set has a second block thickness. The substrate or the electronic component includes receiving portions having a fastened thickness. A thickness of the second block thickness and the fastened thickness is greater than a thickness of the first block thickness and the fastened thickness.

### RELATED APPLICATIONS

This US application claims the benefit of priority to China application no. 202210285920.7, filed on Mar. 22, 2022, of which is incorporated herein by reference in its entirety.

### TECHNICAL FIELD

Example embodiments relate generally to the field of heat dissipation and, more particularly, to universal mounting mechanisms, mounting heat exchange apparatuses to substrates or electronic components.

### BACKGROUND

With the increase of the processing speed and performance of electronic components, such as central processing units (CPUs), the amount of heat generated during operation of the electronic component increases. The heat generation increases the temperature of the electronic component and, if the heat cannot be dissipated effectively, reliability and performance of the electronic component are reduced. To prevent overheating of an electronic component, typically, a liquid cooling apparatus is used for cooling the electronic component and thereby maintaining normal operation of the electronic component.

Existing liquid cooling apparatuses typically include a base plate of a heat exchange chamber attached to a CPU or GPU, as examples, and the heat exchange chamber is fluidly connected to a fluid circulating pump. As an example, all-in-one (AIO) liquid coolers, are third-party liquid cooling apparatuses, typically combining the base plate, heat exchange chamber, and pump all-in-one. The pump circulates the fluid inside the heat exchange chamber in order to deliver the fluid at lower temperature to the heat exchange chamber. As the fluid circulates in the heat exchange chamber, thermal energy is exchanged between the base plate and the fluid and, as a result, the temperature of the base plate is reduced and the temperature of the fluid increases. However, there are different types of liquid cooling apparatuses having various sizes, shapes, base plate thicknesses, and fastening methods. There are also different types of CPU or GPU set-ups on a motherboard also having various sizes, shapes, fastener length requirements due to, as an example, different substrate or set-up thicknesses, and fastening methods. Not all liquid cooling apparatuses can be mounted to all CPU or GPU set-ups on a motherboard due to the various sizes, shapes, thicknesses and fastening methods.

Typically, fixing screws or other fasteners are utilized at four corners of the base plate to screw or fasten the base plate to substrates or electronic components, e.g., CPU or GPU set-ups, for mounting of the liquid cooling apparatuses to the CPU or GPU, assuring heat transfer efficiency. However, fixing of the fixing screws are laborious and the fixing screws or other fasteners are length specific, complicating any change in the liquid cooling apparatus or substrate or electronic component. As an example, fixing screws or other fasteners may not be long enough for mounting of the liquid cooling apparatus and substrate or electronic component. Also, fixing screw or other fastener hole alignments may be off, requiring customization, which is inconvenient and time-consuming.

By not being securely fixed to the substrate or electronic component due to any of the aforementioned, heat transfer efficiency would be compromised, and the CPU or GPU may overheat, causing an electronic component system to crash and fail.

### SUMMARY

Various aspects of the present disclosure provide a universal mounting mechanism for mounting and disengagement of heat exchange apparatuses to substrates or electronic components.

According to one aspect of the present disclosure, a universal mounting mechanism including a mounting bracket and at least one universal fastener assembly is provided. The mounting bracket includes a mounting flange having an attachment surface and a mounting surface opposite the attachment surface. The mounting bracket is configured to mount a liquid-cooling heat exchange apparatus to a substrate or an electronic component. The at least one universal fastener assembly is orthogonally assembled through the mounting bracket from the attachment surface. The at least one universal fastener assembly has a mounted position and a fastened position. The liquid-cooling heat exchange apparatus includes a first liquid-cooling heat exchange apparatus having a first waterblock set or a second liquid-cooling heat exchange apparatus having a second waterblock set. The first waterblock set has a first block thickness, and the second waterblock set has a second block thickness. The thickness of the second block thickness is greater than a thickness of the first block thickness. The substrate or the electronic component includes receiving portions having a fastened thickness. When the at least one universal fastener assembly is assembled and in the fastened position, the at least one universal fastener assembly fastens the first liquid-cooling heat exchange apparatus to the substrate or the electronic component, or the at least one universal fastener assembly fastens the second liquid-cooling heat exchange apparatus to the substrate or the electronic component. A thickness of the second block thickness and the fastened thickness is greater than a thickness of the first block thickness and the fastened thickness.

According to another aspect of the present disclosure, the fastening portion further includes a buttress portion connected to the fastening portion and extended therefrom. The buttress portion is parallel to the bottom plane of the surface 1011/2011 of the waterblock set and the substrate or electronic component. When the at least one universal fastener assembly is assembled and in the fastened position, and the buttress portion contacts the substrate or the electronic component receiving the first liquid-cooling heat exchange apparatus, or the buttress portion contacts the substrate or the electronic component receiving the second liquid-cooling heat exchange apparatus, a tension contact surface area of the buttress portion is greater than a surface area of the tension contact surface points of the plurality of contact tension points, increasing friction surface area.

According to another aspect of the present disclosure, the fastening clip further includes a handle, an attachment portion and a rotating portion. The rotating portion is connected to the extended portion of the fastening leg opposite the buttress portion. The rotating portion is parallel to a plane of the attachment surface. The handle is connected to the rotating portion opposite the extended portion. The handle defines a finger catch. The attachment portion is connected to the handle opposite the rotating portion. When the at least one universal fastener assembly is assembled and in the mounted position, the handle is in a ready position and rotatable. When the at least one universal fastener assembly is assembled and in the fastened position, the handle is in a rotated position. When the handle rotates from the ready position to the rotated position, the fastening leg is rotated, whereby the attachment portion rotates on a first axis and the rotating portion rotates on a second axis different from the first axis.

According to another aspect of the present disclosure, the at least one universal fastener assembly further includes a housing including an anchor structure, and the mounting bracket further includes a pair of vertical flanges extending outwardly from opposing longitudinal edges of the mounting flange. The anchor structure is mounted furthest away and parallel to at least one of the pair of vertical flanges. When the at least one universal fastener assembly is assembled and in the mounted position, the attachment portion is rotatable within the anchor structure and the rotating portion is rotatable within the anchor structure. When the handle rotates from the ready position to the rotated position, the fastening leg is rotated, whereby the attachment portion rotates on the first axis within the anchor structure and the rotating portion rotates on the second axis within the anchor structure.

According to another aspect of the present disclosure, the housing further includes a mounting surface having four opposing corners, and the at least one universal fastener assembly includes a pair of alignment prongs protruding outwardly from the mounting surface. Each of the pair of alignment prongs include a proximal portion, a distal portion, and at least one tightening rail. The proximal portion protrudes outwardly from the mounting surface. The at least one tightening rail protrudes longitudinally along the proximal portion. The distal portion is connected to the proximal portion. A diameter of the proximal portion is greater than a diameter of the distal portion. The fastening leg protrudes outwardly from one corner of the anchor structure via a bracket leg cutout of the mounting flange and a waterblock leg cutout of the waterblock set. The pair of alignment prongs protrude outwardly from two opposing diagonal corners nearest to the one corner of the anchor structure via a pair of bracket passage holes of the mounting flange and a pair of block passage holes of the waterblock set. Each of the pair of bracket passage holes and each of the pair of block passage holes correspond to the pair of alignment prongs. The pair of alignment prongs protruding outwardly from the two opposing diagonal corners, each having at least one tightening rail, the corresponding pair of bracket passage holes and the corresponding pair of block passage holes, are configured to laterally fix the at least one universal fastener assembly orthogonally assembled through the mounting bracket.

According to another aspect of the present disclosure, the first waterblock set further includes a pair of first block passage holes and the second waterblock set further includes a pair of second block passage holes. Each of the pair of bracket passage holes include at least two sub-passage holes in communication thereamong and separated by a distance. One of the at least two sub-passage holes is configured to correspond to the pair of alignment prongs protruding outwardly from the two opposing diagonal corners of the mounting surface of the housing and aligned with the pair of first block passage holes. Another of the at least two sub-passage holes is configured to correspond to the pair of alignment prongs protruding outwardly from the two opposing diagonal corners of the mounting surface of the housing and aligned with the pair of second block passage holes.

According to another aspect of the present disclosure, the amount of the at least one universal fastener assembly includes four, and a shape of the mounting flange of the mounting bracket is quadrilateral shaped. Each of the four at least one universal fastener assembly is orthogonally assembled through the mounting bracket from the attachment surface at each of the four corners of the quadrilateral shaped mounting bracket.

According to another aspect of the present disclosure, the liquid-cooling heat exchange apparatus further includes a liquid pump module disposed on the waterblock set, controlling the liquid-cooling heat exchange apparatus. The liquid pump module includes an inlet and an outlet. The waterblock set further includes a heat exchange chamber and a surface. The surface is configured to dissipate heat from heat generating sources, whereby via the inlet and outlet, the liquid pump module circulates fluid within the heat exchange chamber for cooling the heat generating sources.

According to another aspect of the present disclosure, a liquid-cooling heat exchange apparatus is provided. The liquid-cooling heat exchange apparatus includes a universal mounting mechanism including a mounting bracket and at least one universal fastener assembly is provided. The mounting bracket includes a mounting flange having an attachment surface and a mounting surface opposite the attachment surface. The mounting bracket is configured to mount a liquid-cooling heat exchange apparatus to a substrate or an electronic component. The at least one universal fastener assembly is orthogonally assembled through the mounting bracket from the attachment surface. The at least one universal fastener assembly has a mounted position and a fastened position. The liquid-cooling heat exchange apparatus includes a first liquid-cooling heat exchange apparatus having a first waterblock set or a second liquid-cooling heat exchange apparatus having a second waterblock set. The first waterblock set has a first block thickness, and the second waterblock set has a second block thickness. The thickness of the second block thickness is greater than a thickness of the first block thickness. The substrate or the electronic component includes receiving portions having a fastened thickness. When the at least one universal fastener assembly is assembled and in the fastened position, the at least one universal fastener assembly fastens the first liquid-cooling heat exchange apparatus to the substrate or the electronic component, or the at least one universal fastener assembly fastens the second liquid-cooling heat exchange apparatus to the substrate or the electronic component. A thickness of the second block thickness and the fastened thickness is greater than a thickness of the first block thickness and the fastened thickness.

According to another aspect of the liquid-cooling heat exchange apparatus of the present disclosure, the at least one universal fastener assembly includes a fastening clip including a fastening leg having an extended portion and a fastening portion connected to the extended portion. The fastening portion includes a plurality of contact tension points. When the at least one universal fastener assembly is assembled and in the fastened position, the at least one of the plurality of contact tension points contact the substrate or the electronic component receiving the first liquid-cooling heat exchange apparatus, or the at least one of the plurality of contact tension points contact the substrate or the electronic component receiving the second liquid-cooling heat exchange apparatus, whereby tension contact surface points of the plurality of contact tension points are different tension contact surface points, the different tension contact surface points separated by a distance.

According to another aspect of the liquid-cooling heat exchange apparatus of the present disclosure, the fastening portion further includes a buttress portion connected to the fastening portion and extended therefrom. The buttress portion is parallel to the bottom plane of the surface 1011/2011 of the waterblock set and the substrate or electronic component. When the at least one universal fastener assembly is assembled and in the fastened position, and the buttress portion contacts the substrate or the electronic component receiving the first liquid-cooling heat exchange apparatus, or the buttress portion contacts the substrate or the electronic component receiving the second liquid-cooling heat exchange apparatus, a tension contact surface area of the buttress portion is greater than a surface area of the tension contact surface points of the plurality of contact tension points, increasing friction surface area.

According to another aspect of the liquid-cooling heat exchange apparatus of the present disclosure, the fastening clip further includes a handle, an attachment portion and a rotating portion. The rotating portion is connected to the extended portion of the fastening leg opposite the buttress portion. The rotating portion is parallel to a plane of the attachment surface. The handle is connected to the rotating portion opposite the extended portion. The handle defines a finger catch. The attachment portion is connected to the handle opposite the rotating portion. When the at least one universal fastener assembly is assembled and in the mounted position, the handle is in a ready position and rotatable. When the at least one universal fastener assembly is assembled and in the fastened position, the handle is in a rotated position. When the handle rotates from the ready position to the rotated position, the fastening leg is rotated, whereby the attachment portion rotates on a first axis and the rotating portion rotates on a second axis different from the first axis.

According to another aspect of the liquid-cooling heat exchange apparatus of the present disclosure, the at least one universal fastener assembly further includes a housing including an anchor structure, and the mounting bracket further includes a pair of vertical flanges extending outwardly from opposing longitudinal edges of the mounting flange. The anchor structure is mounted furthest away and parallel to at least one of the pair of vertical flanges. When the at least one universal fastener assembly is assembled and in the mounted position, the attachment portion is rotatable within the anchor structure and the rotating portion is rotatable within the anchor structure. When the handle rotates from the ready position to the rotated position, the fastening leg is rotated, whereby the attachment portion rotates on the first axis within the anchor structure and the rotating portion rotates on the second axis within the anchor structure.

According to another aspect of the liquid-cooling heat exchange apparatus of the present disclosure, the housing further includes a mounting surface having four opposing corners, and the at least one universal fastener assembly includes a pair of alignment prongs protruding outwardly from the mounting surface. Each of the pair of alignment prongs include a proximal portion, a distal portion, and at least one tightening rail. The proximal portion protrudes outwardly from the mounting surface. The at least one tightening rail protrudes longitudinally along the proximal portion. The distal portion is connected to the proximal portion. A diameter of the proximal portion is greater than a diameter of the distal portion. The fastening leg protrudes outwardly from one corner of the anchor structure via a bracket leg cutout of the mounting flange and a waterblock leg cutout of the waterblock set. The pair of alignment prongs protrude outwardly from two opposing diagonal corners nearest to the one corner of the anchor structure via a pair of bracket passage holes of the mounting flange and a pair of block passage holes of the waterblock set. Each of the pair of bracket passage holes and each of the pair of block passage holes correspond to the pair of alignment prongs. The pair of alignment prongs protruding outwardly from the two opposing diagonal corners, each having at least one tightening rail, the corresponding pair of bracket passage holes and the corresponding pair of block passage holes, are configured to laterally fix the at least one universal fastener assembly orthogonally assembled through the mounting bracket.

According to another aspect of the liquid-cooling heat exchange apparatus of the present disclosure, the first waterblock set further includes a pair of first block passage holes and the second waterblock set further includes a pair of second block passage holes. Each of the pair of bracket passage holes include at least two sub-passage holes in communication thereamong and separated by a distance. One of the at least two sub-passage holes is configured to correspond to the pair of alignment prongs protruding outwardly from the two opposing diagonal corners of the mounting surface of the housing and aligned with the pair of first block passage holes. Another of the at least two sub-passage holes is configured to correspond to the pair of alignment prongs protruding outwardly from the two opposing diagonal corners of the mounting surface of the housing and aligned with the pair of second block passage holes.

According to another aspect of the liquid-cooling heat exchange apparatus of the present disclosure, the amount of the at least one universal fastener assembly includes four, and a shape of the mounting flange of the mounting bracket is quadrilateral shaped. Each of the four at least one universal fastener assembly is orthogonally assembled through the mounting bracket from the attachment surface at each of the four corners of the quadrilateral shaped mounting bracket.

According to another aspect of the liquid-cooling heat exchange apparatus of the present disclosure, the liquid-cooling heat exchange apparatus further includes a liquid pump module disposed on the waterblock set, controlling the liquid-cooling heat exchange apparatus. The liquid pump module includes an inlet and an outlet. The waterblock set further includes a heat exchange chamber and a surface. The surface is configured to dissipate heat from heat generating sources, whereby via the inlet and outlet, the liquid pump module circulates fluid within the heat exchange chamber for cooling the heat generating sources.

### BRIEF DESCRIPTION OF THE DRAWINGS

The following figures are included to illustrate certain aspects of the embodiments and should not be viewed as exclusive embodiments. The subject matter disclosed is capable of considerable modifications, alterations, combinations, and equivalents in form and function, as will occur to those of ordinary skill in the relevant art and having the benefit of this disclosure.

FIG. 1 illustrates an exploded view of a universal mounting mechanism and a liquid-cooling heat exchange apparatus, according to disclosed embodiments.

FIG. 2 illustrates an exploded view of the universal mounting mechanism of FIG. 1, according to disclosed embodiments.

FIG. 3 illustrates a perspective view of the universal mounting mechanism of FIG. 1 in a first fastened position, according to disclosed embodiments.

FIG. 4 illustrates another perspective view of the universal mounting mechanism of FIG. 1 in a first fastened position, according to disclosed embodiments.

FIG. 5 illustrates a perspective view of the universal mounting mechanism of FIG. 1 in a second fastened position, according to disclosed embodiments.

FIG. 6 illustrates a perspective view of a universal fastener assembly of the universal mounting mechanism in a second fastened position and the liquid-cooling heat exchange apparatus of FIG. 1, according to disclosed embodiments.

FIG. 7 illustrates a perspective view of the universal fastener assembly of the universal mounting mechanism of FIG. 1 in a first fastened position and another liquid-cooling heat exchange apparatus, according to disclosed embodiments.

FIG. 8 illustrates a perspective view of the universal fastener assembly of FIG. 1, according to disclosed embodiments.

FIG. 9 illustrates another perspective view of the universal fastener assembly of FIG. 1, according to disclosed embodiments.

FIG. 10 illustrates a perspective view of the universal fastener assembly of the universal mounting mechanism in a fastened position and the liquid-cooling heat exchange apparatus of FIG. 1, including a mounted position arrow direction, according to disclosed embodiments.

FIG. 11 illustrates a perspective view of the universal fastener assembly of the universal mounting mechanism rotated to a mounted position and the liquid-cooling heat exchange apparatus of FIG. 10, according to disclosed embodiments.

FIG. 12 illustrates a perspective view of the universal fastener assembly of the universal mounting mechanism in a mounted position and the liquid-cooling heat exchange apparatus of FIG. 10, including a fastened position arrow direction, according to disclosed embodiments.

FIG. 13 illustrates a perspective view of the universal fastener assembly of the universal mounting mechanism rotated to a fastened position and the liquid-cooling heat exchange apparatus of FIG. 10, according to disclosed embodiments.

### DETAILED DESCRIPTION

The following describes various principles related to mounting and disengagement of heat exchange apparatuses to substrates or electronic components by way of reference to specific examples of universal mounting mechanisms, including specific arrangements and examples of mounting brackets and at least one universal fastener assembly embodying innovative concepts. More particularly, but not exclusively, such innovative principles are described in relation to selected examples of bracket passage holes, handles, and fastening legs and well-known functions or constructions are not described in detail for purposes of succinctness and clarity. Nonetheless, one or more of the disclosed principles can be incorporated in various other embodiments of bracket passage holes, handles, and fastening legs to achieve any of a variety of desired outcomes, characteristics, and/or performance criteria.

Thus, universal mounting mechanisms having attributes that are different from those specific examples discussed herein can embody one or more of the innovative principles and can be used in applications not described herein in detail. Accordingly, embodiments not described herein in detail also fall within the scope of this disclosure, as will be appreciated by those of ordinary skill in the relevant art following a review of this disclosure.

In the illustrated embodiments, the substrate or electronic component (not shown) by which the liquid-cooling heat exchange apparatus 1/2 is mounted to via the mounting bracket 10 and receiving portions of the substrate or electronic component, as an example, may be a substrate or electronic component of an electronic component system such as a host, a server, a network switch, or a computer. Additionally, the liquid-cooling heat exchange apparatus 1/2, as an example, may include a waterblock set 101/201 having a base plate (surface 1011/2011) and a heat exchange chamber 1013/(2013 not shown), a liquid pump module 102, tubing (not shown), a radiator having a fan or fans (not shown), and liquid-cooling heat exchange apparatus power cables. The base plate (surface 1011/2011) is in thermal contact with a heat generating source such as a CPU or GPU (not shown), as an example, and the liquid pump module 102 circulates fluid inside the heat exchange chamber 1013/(2013 not shown), exchanging thermal energy between the base plate (surface 1011/2011) and the fluid and reducing the temperature of the base plate (surface 1011/2011) and increasing the temperature of the fluid. The liquid pump module 102 is connected to the radiator (not shown), exchanging thermal energy between the radiator and ambient air, dissipating heat and reducing the temperature of the fluid before repeating the same process again. The shapes and sizes of the liquid-cooling heat exchange apparatus 1/2 and substrate or electronic component may be different. The mounting bracket 10 may be mounted to a backplate attached to the substrate or electronic component. For clarity of illustration, the electronic component system is not shown, and the liquid-cooling heat exchange apparatus 1/2 is simplified, and in practice, both may be varied.

Example embodiments as disclosed herein are directed to universal mounting mechanisms 2 including a mounting bracket 10 configured to mount a liquid-cooling heat exchange apparatus 1/2 to a substrate or an electronic component (not shown) and at least one universal fastener assembly 20. The at least one universal fastener assembly 20 is orthogonally assembled through the mounting bracket 10. The liquid-cooling heat exchange apparatus 1/2 includes a first liquid-cooling heat exchange apparatus 1 having a first waterblock set 101 or a second liquid-cooling heat exchange apparatus 2 having a second waterblock set 201. The first waterblock set 101 has a first block thickness 1T, and the second waterblock set 201 has a second block thickness 2T. The substrate or the electronic component includes receiving portions having a fastened thickness. A thickness of the second block thickness 2T and the fastened thickness is greater than a thickness of the first block thickness 1T and the fastened thickness.

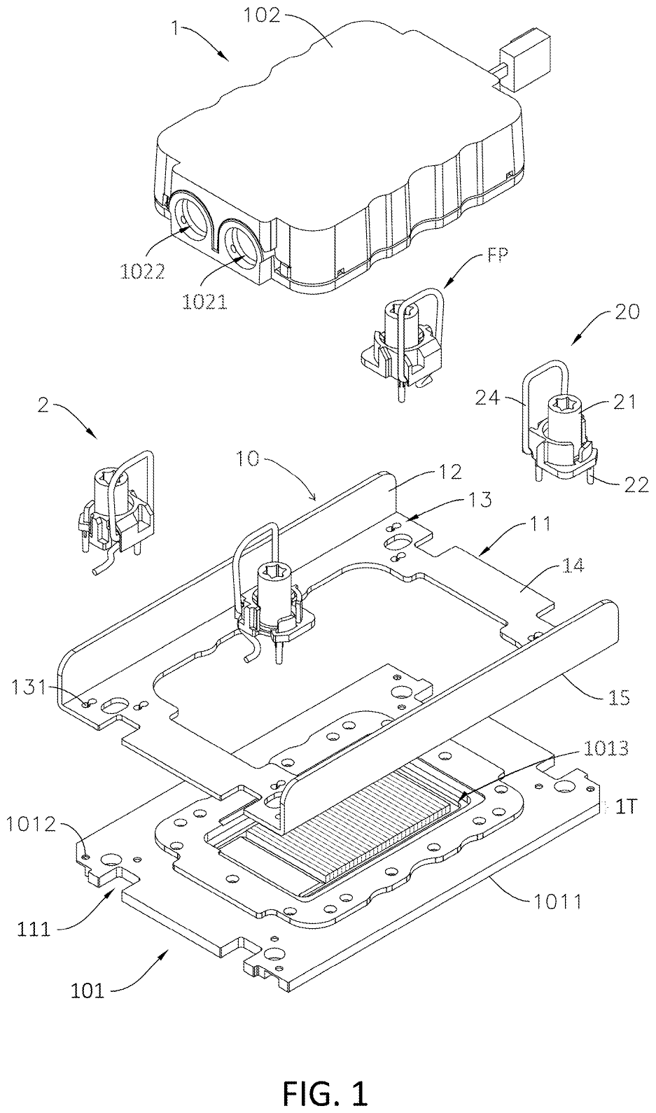

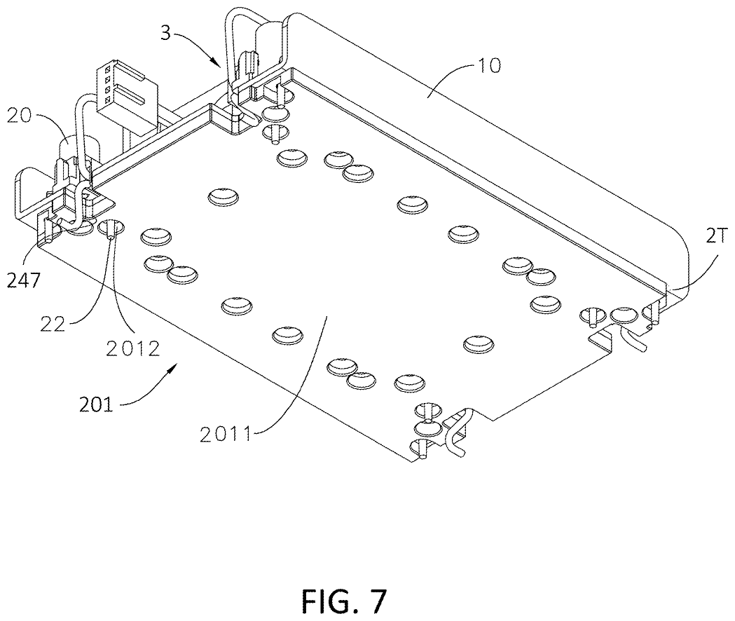

FIG. 1 illustrates an exploded view of a universal mounting mechanism and a liquid-cooling heat exchange apparatus, according to disclosed embodiments. As illustrated in FIG. 1, a universal mounting mechanism 2 including a mounting bracket 10 and at least one universal fastener assembly 20 is provided. The mounting bracket 10 includes a mounting flange 11 having an attachment surface 14 and a mounting surface 15 opposite the attachment surface 14. The mounting bracket 10 is configured to mount a liquid-cooling heat exchange apparatus 1 to a substrate or an electronic component (not shown). The at least one universal fastener assembly 20 is orthogonally assembled through the mounting bracket 10 from the attachment surface 14. The at least one universal fastener assembly 20 has a mounted position MP and a fastened position FP (shown in FIG. 11). The liquid-cooling heat exchange apparatus 1/3 includes a first liquid-cooling heat exchange apparatus 1 having a first waterblock set 101 or a second liquid-cooling heat exchange apparatus 3 having a second waterblock set 201 (shown in FIG. 7). The first waterblock set 101 has a first block thickness 1T and the second waterblock set 201 has a second block thickness 2T. The thickness of the second block thickness 2T is greater than a thickness of the first block thickness 1T. The substrate or the electronic component (not shown) includes receiving portions having a fastened thickness. When the at least one universal fastener assembly 20 is assembled and in the fastened position FP, the at least one universal fastener assembly 20 fastens the first liquid-cooling heat exchange apparatus 1 to the first substrate or the first electronic component (not shown), or the at least one universal fastener assembly 20 fastens the second liquid-cooling heat exchange apparatus 3 to the first substrate or the first electronic component (not shown). A thickness of the second block thickness 2T and the fastened thickness is greater than a thickness of the first block thickness 1T and the fastened thickness.

As illustrated, the liquid-cooling heat exchange apparatus 1/3 further includes a liquid pump module 102 disposed on the waterblock set 101/201, controlling the liquid-cooling heat exchange apparatus 1/3. The liquid pump module 102 includes an inlet 1021 and an outlet 1022. The waterblock set 101/201 further includes a heat exchange chamber 1013/(2013 not shown) and a surface 1011/2011. The surface 1011/2011 is configured to dissipate heat from heat generating sources (not shown), whereby via the inlet 1021 and outlet 1022, the liquid pump module 102 circulates fluid within the heat exchange chamber 1013/(2013 not shown) for cooling the heat generating sources.

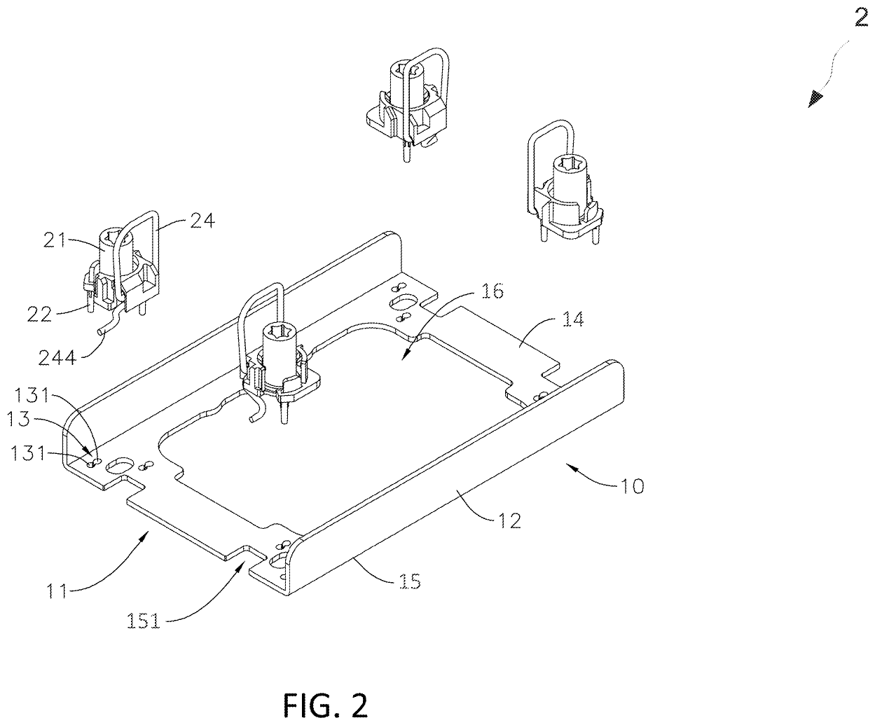

FIG. 2 illustrates an exploded view of the universal mounting mechanism of FIG. 1, according to disclosed embodiments. As illustrated in FIG. 2, and in FIG. 1, the mounting bracket 10 further comprises a waterblock opening 16, an amount of the at least one universal fastener assembly 20 includes four, and a shape of the mounting flange 11 of the mounting bracket 10 is flat quadrilateral shaped and a shape of the waterblock opening 16 is generally quadrilateral shaped. Each of the four at least one universal fastener assembly is orthogonally assembled through the mounting bracket 10 from the attachment surface 14 at each of the four corners of the quadrilateral shaped mounting bracket 10.

In the illustrated embodiments, the shapes of the liquid-cooling heat exchange apparatus 1/3 and the waterblock set 101/201 are generally quadrilateral shaped and the shapes of the mounting flange 11 and waterblock set opening 16 are generally quadrilateral shaped, whereby the shape of the waterblock set opening 16 correspond to the shape of an extended perimeter surrounding the heat exchange chamber 1013/(2013 not shown); however, the embodiments are not limited thereto. The shape and size of the liquid-cooling heat exchange apparatus and the waterblock set may be varied and the shapes of the mounting flange and waterblock set opening may be varied. As long as the shape of the waterblock set opening correspond to the shape of an extended perimeter surrounding the heat exchange chamber, and the universal mounting mechanism 2 is configured to mount a liquid-cooling heat exchange apparatus to a substrate or an electronic component (not shown).

Referring again to the illustration of FIG. 1, the substrate or the electronic component (not shown) includes receiving portions having a fastened thickness; however, the embodiments are not limited thereto. As an example, the substrate or the electronic component (not shown) may include more than one substrate or electronic component having different fastened thicknesses. As long as the universal mounting mechanism 2 is configured to mount the liquid-cooling heat exchange apparatuses 1/3 to the substrates or electronic components.

In an embodiment, the substrate or the electronic component includes a first substrate or a first electronic component (not shown), both having a first receiving portions including a first thickness 1T and a second substrate or a second electronic component (not shown), both having a second receiving portions including a second thickness 2T. The thickness of the second thickness 2T is greater than a thickness of the first thickness 1T. When the at least one universal fastener assembly 20 is assembled and in the fastened position FP, the at least one universal fastener assembly 20 fastens the first liquid-cooling heat exchange apparatus 1 to the second substrate or the second electronic component, or the at least one universal fastener assembly 20 fastens the second liquid-cooling heat exchange apparatus 3 to the second substrate or the second electronic component, whereby a thickness of the second block thickness 2T and the second thickness may be greater than the thickness of the second block thickness 2T and the first thickness, the thickness of the second block thickness 2T and the first thickness may be greater than a thickness of the first block thickness 1T and the first thickness, and a thickness of the first block thickness 1T and the second thickness may be greater than the thickness of the first block thickness 1T and the first thickness.

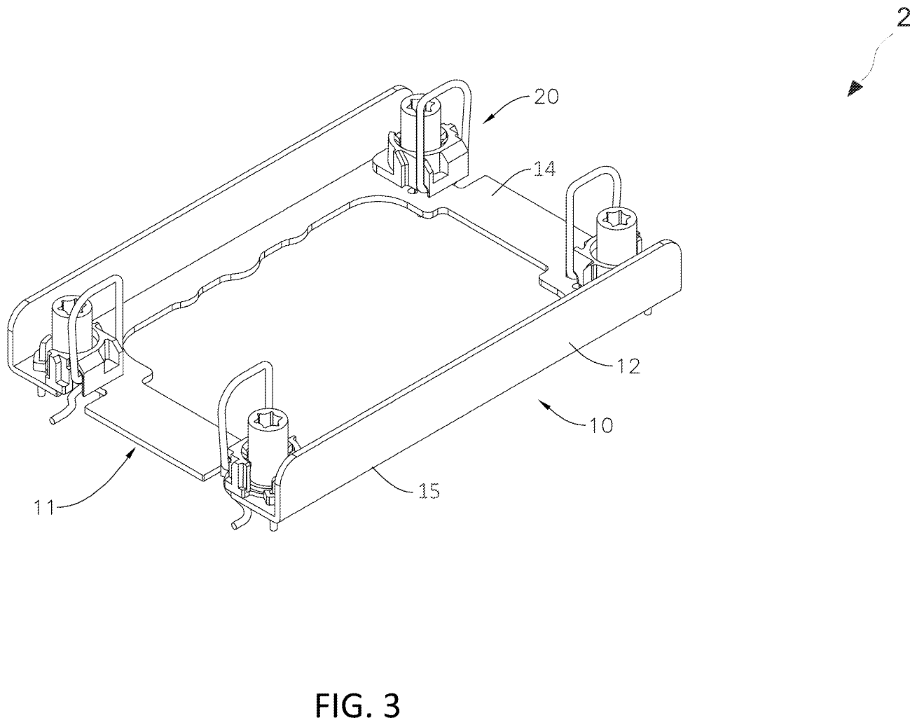

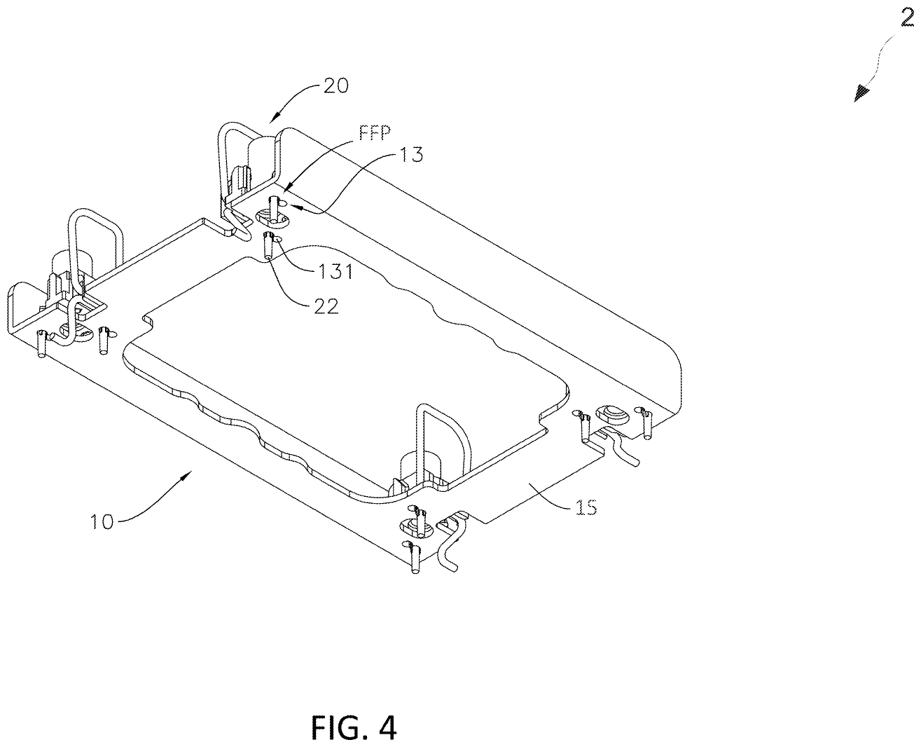

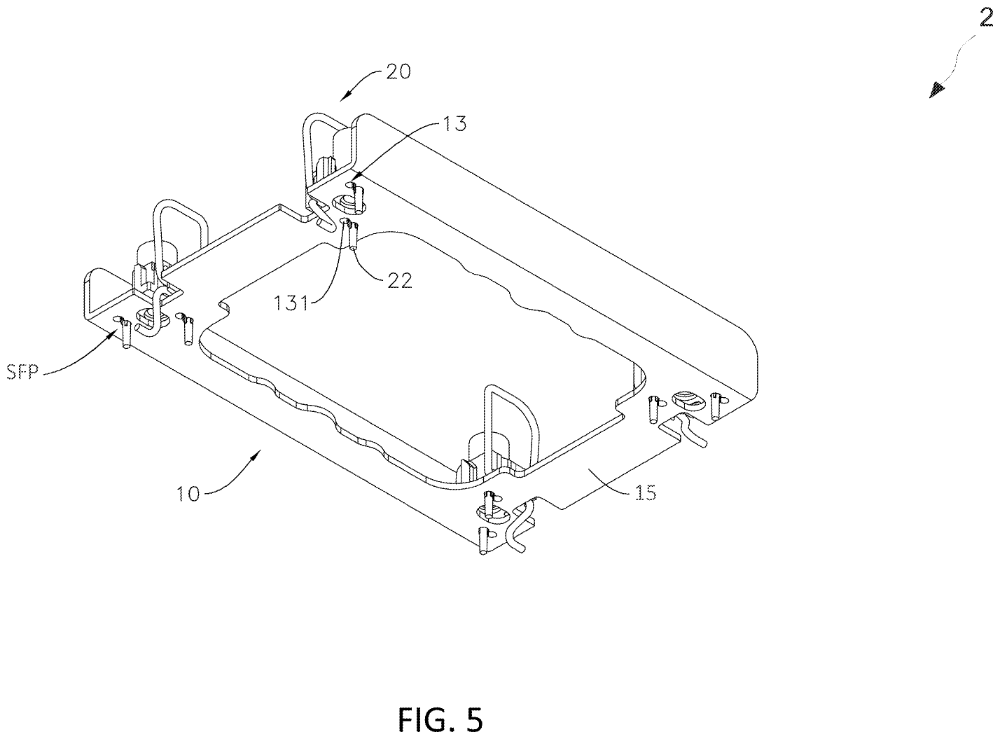

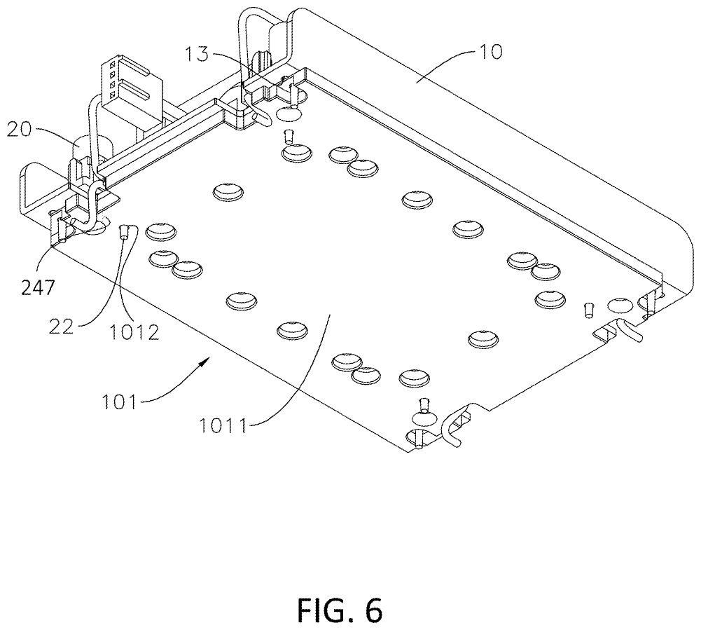

FIGS. 3 and 4 illustrate perspective views of the universal mounting mechanism of FIG. 1 in a first fastened position FFP, according to disclosed embodiments. FIG. 5 illustrates a perspective view of the universal mounting mechanism of FIG. 1 in a second fastened position SFP, according to disclosed embodiments. FIG. 6 illustrates a perspective view of a universal fastener assembly of the universal mounting mechanism in a second fastened position SFP and the liquid-cooling heat exchange apparatus of FIG. 1, according to disclosed embodiments. FIG. 7 illustrates a perspective view of the universal fastener assembly of the universal mounting mechanism of FIG. 1 in a first fastened position FFP and another liquid-cooling heat exchange apparatus, according to disclosed embodiments. As illustrated in FIGS. 3 to 7, and FIGS. 1 to 2, the first waterblock set 101 further includes a pair of first block passage holes 1012 and the second waterblock set 201 further includes a pair of second block passage holes 2012. The mounting flange 11 further includes a pair of bracket passage holes 13. Each of the pair of bracket passage holes 13 include at least two sub-passage holes 131 in communication thereamong and separated by a distance. One of the at least two sub-passage holes 131 is configured to correspond to the pair of alignment prongs 22 protruding outwardly from the two opposing diagonal corners of the mounting surface 15 of the housing 24 and aligned with the pair of first block passage holes 1012. Another of the at least two sub-passage holes 131 is configured to correspond to the pair of alignment prongs 22 protruding outwardly from the two opposing diagonal corners of the mounting surface 15 of the housing 24 and aligned with the pair of second block passage holes 2012.

In the illustrated embodiments, the pair of bracket passage holes 13 include at least two sub-passage holes 131 in communication thereamong, double-hole hourglass shaped, and separated by a distance; however, the embodiments are not limited thereto. The pair of bracket passage holes may include more than two sub-passage holes in communication thereamong and separated by a distance. As long as the sub-passage holes are configured to correspond to the pair of alignment prongs 22 protruding outwardly from the two opposing diagonal corners of the mounting surface 15 of the housing 24 and aligned with the pair of block passage holes 1012/2012 of the waterblock set 101/201 and receiving portions of the substrate or electronic component.

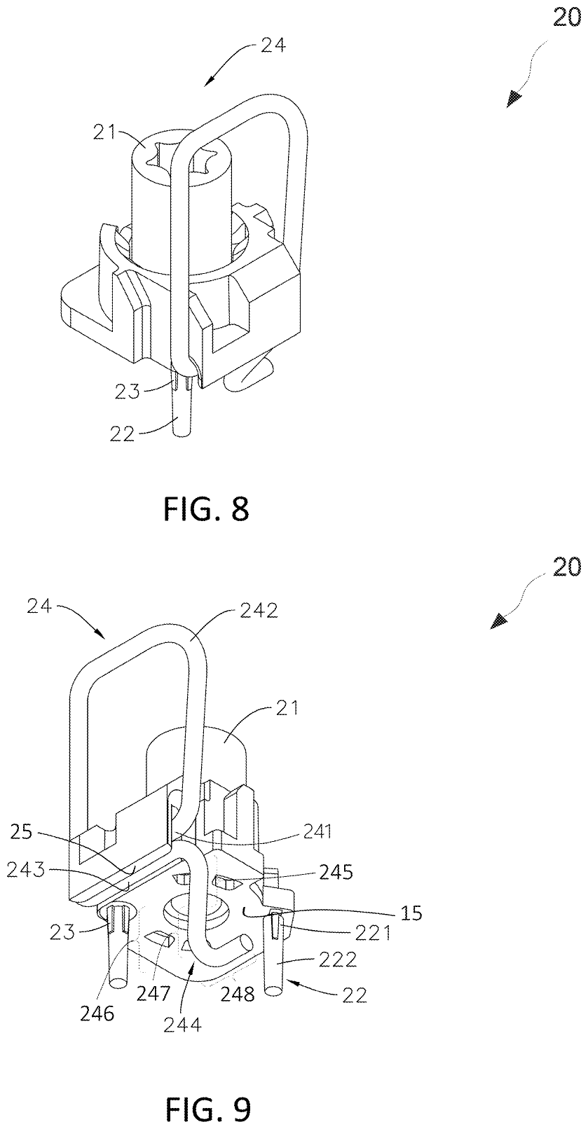

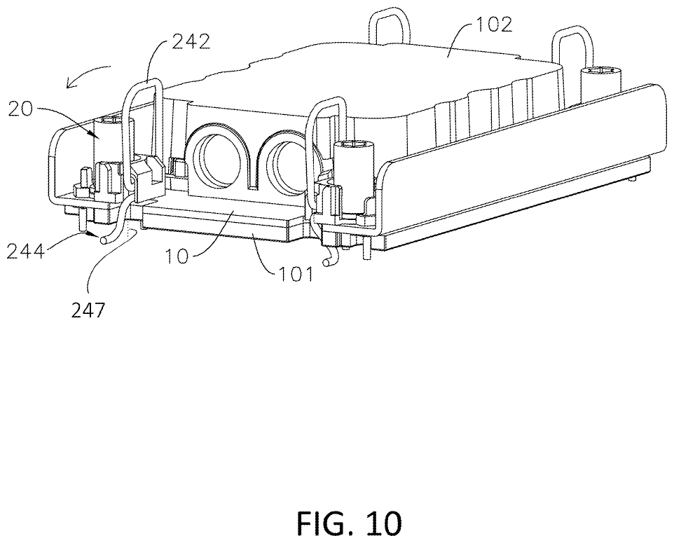

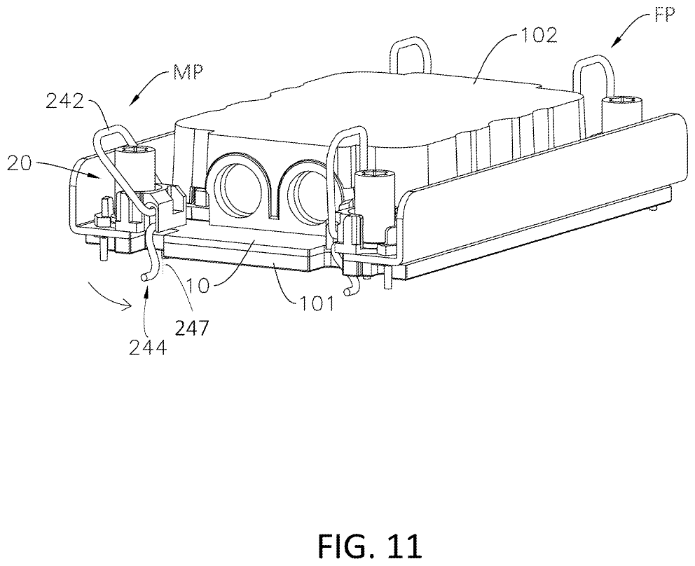

FIG. 8 and FIG. 9 illustrates perspective views of the universal fastener assembly of FIG. 1, according to disclosed embodiments. FIG. 10 illustrates a perspective view of the universal fastener assembly of the universal mounting mechanism in a fastened position and the liquid-cooling heat exchange apparatus of FIG. 1, including a mounted position arrow direction, according to disclosed embodiments. As illustrated in FIGS. 8 to 10, and in FIGS. 1 to 7, the at least one universal fastener assembly 20 includes a fastening clip 24 including a fastening leg 244 having an extended portion 245 and a fastening portion 246 connected to the extended portion 245. The fastening portion 246 includes a plurality of contact tension points 247. When the at least one universal fastener assembly 20 is assembled and in the mounted position MP, at least a portion of the fastening leg 244 protrudes outwardly from a bottom plane of the surface 1011/2011 of the waterblock set 101/201 and substrate or the electronic component. When the at least one universal fastener assembly 20 is assembled and in the fastened position FP, the at least one of the plurality of contact tension points 247 contact a bottom edge of the substrate or the electronic component (not shown) receiving the first liquid-cooling heat exchange apparatus 1, or the at least one of the plurality of contact tension points 247 contact a bottom edge of the substrate or the electronic component (not shown) receiving the second liquid-cooling heat exchange apparatus 3, whereby tension contact surface points of the plurality of contact tension points 247 are different tension contact surface points, the different tension contact surface points separated by a distance.

As illustrated, the fastening portion 246 further includes a buttress portion 248 connected to the fastening portion 246 and extended therefrom. The buttress portion 248 is parallel to the bottom plane of the surface 1011/2011 of the waterblock set 101/201 and the substrate or electronic component (not shown). When the at least one universal fastener assembly 20 is assembled and in the fastened position FP, and the buttress portion 248 contacts the bottom edge of the substrate or the electronic component receiving the first liquid-cooling heat exchange apparatus 1, or the buttress portion 248 contacts the bottom edge of the substrate or the electronic component receiving the second liquid-cooling heat exchange apparatus 3, a tension contact surface area of the buttress portion 248 is greater than a surface area of the tension contact surface points of the plurality of contact tension points 247, increasing friction surface area for mounting of the liquid-cooling heat exchange apparatus 1/3 to the substrate or electronic component.

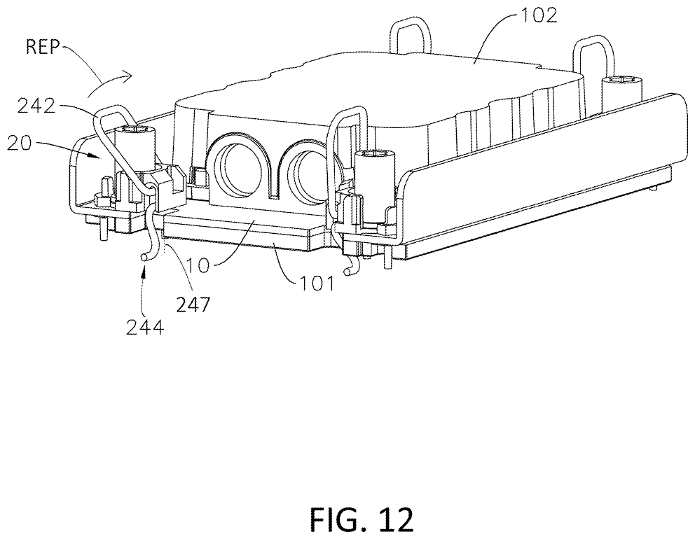

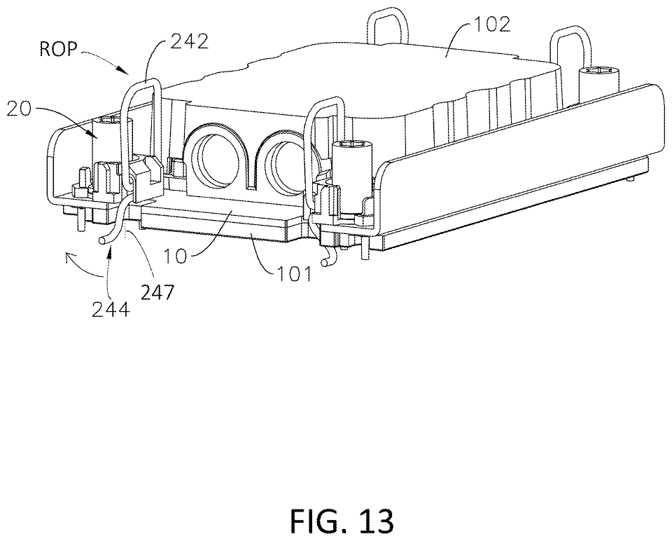

FIG. 11 illustrates a perspective view of the universal fastener assembly of the universal mounting mechanism rotated to a mounted position and the liquid-cooling heat exchange apparatus of FIG. 10, according to disclosed embodiments. FIG. 12 illustrates a perspective view of the universal fastener assembly of the universal mounting mechanism in a mounted position and the liquid-cooling heat exchange apparatus of FIG. 10, including a fastened position arrow direction, according to disclosed embodiments. FIG. 13 illustrates a perspective view of the universal fastener assembly of the universal mounting mechanism rotated to a fastened position and the liquid-cooling heat exchange apparatus of FIG. 10, according to disclosed embodiments. As illustrated in FIGS. 11 to 13, and FIGS. 1 to 10, the fastening clip 24 further includes a handle 242, an attachment portion 241 and a rotating portion 243. The rotating portion 243 is connected to the extended portion 245 of the fastening leg 244 opposite the buttress portion 248. The rotating portion 243 is parallel to a plane of the attachment surface 14. The handle 242 is connected to the rotating portion 243 opposite the extended portion 245. The handle 242 defines a finger catch. The attachment portion 241 is connected to the handle 242 opposite the rotating portion 243. When the at least one universal fastener assembly 20 is assembled and in the mounted position MP, the handle 242 is in a ready position and rotatable REP. When the at least one universal fastener assembly 20 is assembled and in the fastened position FP, the handle 242 is in a rotated position ROP. When the handle 242 rotates from the ready position REP to the rotated position ROP, the fastening leg 244 is rotated, whereby the attachment portion 241 rotates on a first axis and the rotating 243 portion rotates on a second axis different from the first axis.

As illustrated, the at least one universal fastener assembly 20 further includes a housing 24 including an anchor structure 25, and the mounting bracket 10 further includes a pair of vertical flanges 12 extending outwardly from opposing longitudinal edges of the mounting flange 11, forming guard-like rails for the at least one universal fastener assembly 20. The anchor structure 25 is mounted furthest away and parallel to at least one of the pair of vertical flanges 12. When the at least one universal fastener assembly 20 is assembled and in the mounted position MP, the attachment portion 241 is rotatable within the anchor structure 25 and the rotating portion 243 is rotatable within the anchor structure 25. When the handle 242 rotates from the ready position REP to the rotated position ROP, the fastening leg 244 is rotated, whereby the attachment portion 241 rotates on the first axis within the anchor structure 25 and the rotating 243 portion rotates on the second axis within the anchor structure 25.

As illustrated, the housing 24 further includes a mounting surface 15 having four opposing corners, a retention nut 21 disposed centrally within the at least one universal fastener assembly 20, opposite the mounting surface 15, and the at least one universal fastener assembly 20 includes a pair of alignment prongs 22 protruding outwardly from the mounting surface 15. Each of the pair of alignment prongs 22 include a proximal portion 221, a distal portion 222, and at least one tightening rail 23. The proximal portion 221 protrudes outwardly from the mounting surface 15. The at least one tightening rail 23 protrudes longitudinally along the proximal portion 221. The distal portion 222 is connected to the proximal portion 221. A diameter of the proximal portion 221 is greater than a diameter of the distal portion 222. The fastening leg 244 protrudes outwardly from one corner of the anchor structure 25 via a bracket leg cutout 151 of the mounting flange 11 and a waterblock leg cutout 111 of the waterblock set 101/201. The pair of alignment prongs 22 protrude outwardly from two opposing diagonal corners nearest to the one corner of the anchor structure 25 via a pair of bracket passage holes 13 of the mounting flange 11 and a pair of block passage holes 1012 of the waterblock set 101/201. Each of the pair of bracket passage holes 13 and each of the pair of block passage holes 1012 correspond to the pair of alignment prongs 22. The pair of alignment prongs 22 protruding outwardly from the two opposing diagonal corners, each having at least one tightening rail 23, the corresponding pair of bracket passage holes 13 and the corresponding pair of block passage holes 1012, are configured to laterally fix the at least one universal fastener assembly 20 orthogonally assembled through the mounting bracket 10.

In the illustrated embodiments, a diameter of the proximal portion 221 is greater than a diameter of the distal portion 222 for ease of orthogonally assembly of the at least one universal fastener assembly 20 through the mounting bracket 10, waterblock set 101/102 of the liquid-cooling heat exchange apparatus 1/3 and receiving portions of the substrate or electronic component (not shown); however, the embodiments are not limited thereto. The diameter of the proximal portion 221 may be the same as the diameter of the distal portion 222 or the diameters of the proximal portion 221 and the distal portion 222 may be tapering and varied throughout. In the illustrated embodiments, each of the pair of alignment prongs 22 include at least one tightening rail 23 for laterally fixing of the at least one universal fastener assembly 20 though the mounting bracket 10, waterblock set 101/102 of the liquid-cooling heat exchange apparatus 1/3 and receiving portions of the substrate or electronic component (not shown); however, the embodiments are not limited thereto. Each of the pair of alignment prongs 22 may not include the at least one tightening rail 23. As long the at least one universal fastener assembly 20 may be orthogonally assembled through the mounting bracket 10, waterblock set 101/102 of the liquid-cooling heat exchange apparatus 1/3, and receiving portions of the substrate or electronic component (not shown).

In the illustrated embodiments, the at least one universal fastener assembly 20 is orthogonally assembled through the pair of bracket passage holes 13 and bracket leg cutout 151 of the mounting bracket 10, through the pair of block passage holes 1012/2012 and the waterblock leg cutout 111 of the waterblock set 101/102 of the liquid-cooling heat exchange apparatus 1/3, and through the receiving portions of the substrate or electronic component (not shown) for mounting of the liquid-cooling heat exchange apparatus 1/3 to, as examples, a CPU or GPU mounted to a substrate or electronic component. The shape of the waterblock set opening 16 correspond to the shape of the extended perimeter surrounding the heat exchange chamber 1013/(2013 not shown) of the liquid-cooling heat exchange apparatus 1/3, and the mounting bracket 10 and the two positions of the at least one universal fastener assembly 20, the mounted position MP and fastened position FP, quickly and easily mount and disengage the liquid-cooling heat exchange apparatus 1/3 from the substrate or electronic component. The at least one universal fastener assembly 20 is orthogonally assembled in the mounted position MP, wherein the handle 242 is in a ready position REP and the fastening leg 244 protrudes outwardly from a bottom plane of the surface 1011/2011 of the waterblock set 101/201 and substrate or the electronic component (not shown). For fastening, the handle 242 is rotated and secured to the rotated position ROP, wherein the fastening leg 244 is rotated and the at least one of the plurality of contact tension points 247 or the buttress portion 248 of the fastening leg 244 contacts the bottom edge of the substrate or the electronic component receiving the liquid-cooling heat exchange apparatuses 1/3 for mounting of the liquid-cooling heat exchange apparatus 1/3 to, as examples, a CPU or GPU mounted to a substrate or electronic component. The plurality of contact tension points 247 and the buttress portion 248 allow for mounting of liquid-cooling heat exchange apparatuses having different thicknesses to substrates or electronic components, which may also have different thicknesses, simplifying changing of the liquid cooling apparatus or substrate or electronic component which result in different mounting thicknesses. The at least two sub-passage holes 131 of the pair of bracket passage holes 13, the bracket leg cutout 151, and waterblock leg cutout 111, allow for orthogonal assembly through different alignment of holes of the liquid-cooling heat exchange apparatus 1/3, expanding choices for changing of the liquid cooling apparatus or substrate or electronic component which result in different fastening alignment of holes for mounting, whereby the pair of alignment prongs 22 laterally fix the at least one universal fastener assembly 20 orthogonally assembled through the mounting bracket 10.

Referring again to the illustration of FIG. 1, the liquid-cooling heat exchange apparatus 1/3 including the universal mounting mechanism 2 having the mounting bracket 10 and at least one universal fastener assembly 20 is provided. Thus, the liquid-cooling heat exchange apparatus 1/3 including the universal mounting mechanism 2 having the mounting bracket 10 and at least one universal fastener assembly 20 may be best understood with reference to the above as like numerals designate like components which may not be described again in detail for brevity.

In the illustrated embodiments, the mounting bracket 10 includes a mounting flange 11 having an attachment surface 14 and a mounting surface 15 opposite the attachment surface 14. The mounting bracket 10 is configured to mount a liquid-cooling heat exchange apparatus 1 to a substrate or an electronic component (not shown). The at least one universal fastener assembly 20 is orthogonally assembled through the mounting bracket 10 from the attachment surface 14. The at least one universal fastener assembly 20 has a mounted position MP and a fastened position FP. The liquid-cooling heat exchange apparatus 1/3 includes a first liquid-cooling heat exchange apparatus 1 having a first waterblock set 101 or a second liquid-cooling heat exchange apparatus 3 having a second waterblock set 201. The first waterblock set 101 has a first block thickness 1T and the second waterblock set 201 has a second block thickness 2T. The thickness of the second block thickness 2T is greater than a thickness of the first block thickness 1T. The substrate or the electronic component (not shown) includes receiving portions having a fastened thickness. When the at least one universal fastener assembly 20 is assembled and in the fastened position FP, the at least one universal fastener assembly 20 fastens the first liquid-cooling heat exchange apparatus 1 to the first substrate or the first electronic component (not shown), or the at least one universal fastener assembly 20 fastens the second liquid-cooling heat exchange apparatus 3 to the first substrate or the first electronic component (not shown). A thickness of the second block thickness 2T and the fastened thickness, is greater than a thickness of the first block thickness 1T and the fastened thickness.

Referring again to the illustration of FIG. 2, and the illustration of FIG. 1, the mounting bracket 10 further comprises a waterblock opening 16, an amount of the at least one universal fastener assembly 20 includes four, and a shape of the mounting flange 11 of the mounting bracket 10 is flat quadrilateral shaped and a shape of the waterblock opening 16 is generally quadrilateral shaped. Each of the four at least one universal fastener assembly 20 is orthogonally assembled through the mounting bracket 10 from the attachment surface 14 at each of the four corners of the quadrilateral shaped mounting bracket 10.

Referring again to the illustration of FIG. 1, the substrate or the electronic component (not shown) includes receiving portions having a fastened thickness; however, the embodiments are not limited thereto. As an example, the substrate or the electronic component (not shown) may include more than one substrate or electronic component having different fastened thicknesses. As long as the universal mounting mechanism 2 is configured to mount the liquid-cooling heat exchange apparatuses 1/3 to the substrates or electronic components.

In an embodiment, the substrate or the electronic component includes a first substrate or a first electronic component (not shown), both having a first receiving portions including a first thickness 1T and a second substrate or a second electronic component (not shown), both having a second receiving portions including a second thickness 2T. The thickness of the second thickness 2T is greater than a thickness of the first thickness 1T. When the at least one universal fastener assembly 20 is assembled and in the fastened position FP, the at least one universal fastener assembly 20 fastens the first liquid-cooling heat exchange apparatus 1 to the second substrate or the second electronic component, or the at least one universal fastener assembly 20 fastens the second liquid-cooling heat exchange apparatus 3 to the second substrate or the second electronic component, whereby a thickness of the second block thickness 2T and the second thickness may be greater than the thickness of the second block thickness 2T and the first thickness, the thickness of the second block thickness 2T and the first thickness may be greater than a thickness of the first block thickness 1T and the first thickness, and a thickness of the first block thickness 1T and the second thickness may be greater than the thickness of the first block thickness 1T and the first thickness.

Referring again to the illustrations in FIGS. 3 to 7, and FIGS. 1 to 2, the first waterblock set 101 further includes a pair of first block passage holes 1012 and the second waterblock set 201 further includes a pair of second block passage holes 2012. Each of the pair of bracket passage holes 13 include at least two sub-passage holes 131 in communication thereamong and separated by a distance. One of the at least two sub-passage holes 131 is configured to correspond to the pair of alignment prongs 22 protruding outwardly from the two opposing diagonal corners of the mounting surface 15 of the housing 24 and aligned with the pair of first block passage holes 1012. Another of the at least two sub-passage holes 131 is configured to correspond to the pair of alignment prongs 22 protruding outwardly from the two opposing diagonal corners of the mounting surface 15 of the housing 24 and aligned with the pair of second block passage holes 2012.

Referring again to the illustrations in FIGS. 8 to 10, and FIGS. 1 to 7, the at least one universal fastener assembly 20 includes a fastening clip 24 including a fastening leg 244 having an extended portion 245 and a fastening portion 246 connected to the extended portion 245. The fastening portion 246 includes a plurality of contact tension points 247. When the at least one universal fastener assembly 20 is assembled and in the mounted position MP, at least a portion of the fastening leg 244 protrudes outwardly from a bottom plane of the surface 1011/2011 of the waterblock set 101/201 and substrate or the electronic component. When the at least one universal fastener assembly 20 is assembled and in the fastened position FP, the at least one of the plurality of contact tension points 247 contact a bottom edge of the substrate or the electronic component (not shown) receiving the first liquid-cooling heat exchange apparatus 1, or the at least one of the plurality of contact tension points 247 contact a bottom edge of the substrate or the electronic component (not shown) receiving the second liquid-cooling heat exchange apparatus 3, whereby tension contact surface points of the plurality of contact tension points 247 are different tension contact surface points, the different tension contact surface points separated by a distance.

In the illustrated embodiments, the fastening portion 246 further includes a buttress portion 248 connected to the fastening portion 246 and extended therefrom. The buttress portion 248 is parallel to the bottom plane of the surface 1011/2011 of the waterblock set 101/201 and the substrate or electronic component (not shown). When the at least one universal fastener assembly 20 is assembled and in the fastened position FP, and the buttress portion 248 contacts the bottom edge of the substrate or the electronic component receiving the first liquid-cooling heat exchange apparatus 1, or the buttress portion 248 contacts the bottom edge of the substrate or the electronic component receiving the second liquid-cooling heat exchange apparatus 3, a tension contact surface area of the buttress portion 248 is greater than a surface area of the tension contact surface points of the plurality of contact tension points 247, increasing friction surface area for mounting of the liquid-cooling heat exchange apparatus 1/3 to the substrate or electronic component.

Referring again to the illustrations of FIGS. 11 to 13, and FIGS. 1 to 10, the fastening clip 24 further includes a handle 242, an attachment portion 241 and a rotating portion 243. The rotating portion 243 is connected to the extended portion 245 of the fastening leg 244 opposite the buttress portion 248. The rotating portion 243 is parallel to a plane of the attachment surface 14. The handle 242 is connected to the rotating portion 243 opposite the extended portion 245. The handle 242 defines a finger catch. The attachment portion 241 is connected to the handle 242 opposite the rotating portion 243. When the at least one universal fastener assembly 20 is assembled and in the mounted position MP, the handle 242 is in a ready position and rotatable REP. When the at least one universal fastener assembly 20 is assembled and in the fastened position FP, the handle 242 is in a rotated position ROP. When the handle 242 rotates from the ready position REP to the rotated position ROP, the fastening leg 244 is rotated, whereby the attachment portion 241 rotates on a first axis and the rotating 243 portion rotates on a second axis different from the first axis.

In the illustrated embodiments, the at least one universal fastener assembly 20 further includes a housing 24 including an anchor structure 25, and the mounting bracket 10 further includes a pair of vertical flanges 12 extending outwardly from opposing longitudinal edges of the mounting flange 11, forming guard-like rails for the at least one universal fastener assembly 20. The anchor structure 25 is mounted furthest away and parallel to at least one of the pair of vertical flanges 12. When the at least one universal fastener assembly 20 is assembled and in the mounted position MP, the attachment portion 241 is rotatable within the anchor structure 25 and the rotating portion 243 is rotatable within the anchor structure 25. When the handle 242 rotates from the ready position REP to the rotated position ROP, the fastening leg 244 is rotated, whereby the attachment portion 241 rotates on the first axis within the anchor structure 25 and the rotating 243 portion rotates on the second axis within the anchor structure 25.

In the illustrated embodiments, the housing 24 further includes a mounting surface 15 having four opposing corners, a retention nut 21 disposed centrally within the at least one universal fastener assembly 20, opposite the mounting surface 15, and the at least one universal fastener assembly 20 includes a pair of alignment prongs 22 protruding outwardly from the mounting surface 15. Each of the pair of alignment prongs 22 include a proximal portion 221, a distal portion 222, and at least one tightening rail 23. The proximal portion 221 protrudes outwardly from the mounting surface 15. The at least one tightening rail 23 protrudes longitudinally along the proximal portion 221. The distal portion 222 is connected to the proximal portion 221. A diameter of the proximal portion 221 is greater than a diameter of the distal portion 222. The fastening leg 244 protrudes outwardly from one corner of the anchor structure 25 via a bracket leg cutout 151 of the mounting flange 11 and a waterblock leg cutout 111 of the waterblock set 101/201. The pair of alignment prongs 22 protrude outwardly from two opposing diagonal corners nearest to the one corner of the anchor structure 25 via a pair of bracket passage holes 13 of the mounting flange 11 and a pair of block passage holes 1012 of the waterblock set 101/201. Each of the pair of bracket passage holes 13 and each of the pair of block passage holes 1012 correspond to the pair of alignment prongs 22. The pair of alignment prongs 22 protruding outwardly from the two opposing diagonal corners, each having at least one tightening rail 23, the corresponding pair of bracket passage holes 13 and the corresponding pair of block passage holes 1012, are configured to laterally fix the at least one universal fastener assembly orthogonally assembled through the mounting bracket 10.

In the illustrated embodiments, a diameter of the proximal portion 221 is greater than a diameter of the distal portion 222 for ease of orthogonally assembly of the at least one universal fastener assembly 20 through the mounting bracket 10, waterblock set 101/102 of the liquid-cooling heat exchange apparatus 1/3 and receiving portions of the substrate or electronic component (not shown); however, the embodiments are not limited thereto. The diameter of the proximal portion 221 may be the same as the diameter of the distal portion 222 or the diameters of the proximal portion 221 and the distal portion 222 may be tapering and varied throughout. In the illustrated embodiments, each of the pair of alignment prongs 22 include at least one tightening rail 23 for laterally fixing of the at least one universal fastener assembly 20 though the mounting bracket 10, waterblock set 101/102 of the liquid-cooling heat exchange apparatus 1/3 and receiving portions of the substrate or electronic component (not shown); however, the embodiments are not limited thereto. Each of the pair of alignment prongs 22 may not include the at least one tightening rail 23. As long the at least one universal fastener assembly 20 may be orthogonally assembled through the mounting bracket 10, waterblock set 101/102 of the liquid-cooling heat exchange apparatus 1/3, and receiving portions of the substrate or electronic component (not shown).

A universal mounting mechanism 2 including a mounting bracket 10 configured to mount a liquid-cooling heat exchange apparatus 1/3 to and disengage the liquid-cooling heat exchange apparatus 1/3 from a substrate or an electronic component (not shown) and at least one universal fastener assembly is provided. The liquid-cooling heat exchange apparatus 1/3 includes a first liquid-cooling heat exchange apparatus 1 having a first waterblock set 101 or a second liquid-cooling heat exchange apparatus 3 having a second waterblock set 201. The first waterblock set 101 has a first block thickness 1T and the second waterblock set 201 has a second block thickness 2T. The substrate or the electronic component includes receiving portions having a fastened thickness. A thickness of the second block thickness 2T and the fastened thickness is greater than a thickness of the first block thickness 1T and the fastened thickness. The at least one universal fastener assembly 20 is orthogonally assembled through the mounting bracket 10, waterblock set 101/102 of the liquid-cooling heat exchange apparatus 1/3, and the substrate or electronic component.

In the illustrated embodiments, the at least one universal fastener assembly 20 is orthogonally assembled through the pair of bracket passage holes 13 and bracket leg cutout 151 of the mounting bracket 10, through the pair of block passage holes 1012/2012 and the waterblock leg cutout 111 of the waterblock set 101/102 of the liquid-cooling heat exchange apparatus 1/3, and through the receiving portions of the substrate or electronic component (not shown) for mounting of the liquid-cooling heat exchange apparatus 1/3 to, as examples, a CPU or GPU mounted to a substrate or electronic component. The mounting bracket 10 and the two positions of the at least one universal fastener assembly 20, the mounted position MP and fastened position FP, allow for quick and easy mounting and disengaging of the liquid-cooling heat exchange apparatus 1/3 from the substrate or electronic component. Laborious mounting of the liquid-cooling heat exchange apparatus 1/3 to the substrate or electronic component via, for example, screws or other fasteners, are not required, saving mounting and disengaging time. Also, time to find or time and cost to replace the small screws and fasteners which may be easily misplaced, lost, or get stuck in tight places is eliminated.

Also in the illustrated embodiments, the distance separated tension contact surface points of the plurality of contact tension points 247 and the buttress portion 248, both of the fastening portion 246 of the fastening leg 244 of the at least one universal fastener assembly 20, may all contact the bottom edge of the substrate or electronic component (not shown). Thus, while the thickness of the second block thickness 2T and the fastened thickness may be greater than the thickness of the first block thickness 1T and the fastened thickness, the at least one universal fastener assembly 20 may still be orthogonally assembled through one of the at least two sub-passage holes 131 of the pair of bracket passage holes 13 of the mounting bracket 10, through the pair of block passage holes 1012/2012 and the waterblock leg cutout 111 of the waterblock set 101/102 of the liquid-cooling heat exchange apparatus 1/3, and through the receiving portions of the substrate or electronic component (not shown) for mounting of the liquid-cooling heat exchange apparatus 1/3 to, as examples, a CPU or GPU mounted to a substrate or electronic component. The universal mounting mechanism 2 is configured to mount liquid-cooling heat exchange apparatuses 1/3 having different thicknesses to substrates or electronic components, simplifying changing of the liquid cooling apparatus or substrate or electronic component which result in different mounting thicknesses. Moreover, friction surface area is increased by the buttress portion 248 having the tension contact surface area being greater than the surface area of the tension contact surface points of the plurality of contact tension points 247 for secure mounting of the liquid-cooling heat exchange apparatus 1/3 to the CPU or GPU mounted to the substrate or electronic component.

Also in the illustrated embodiments, the hourglass shaped at least two sub-passage holes 131 of the pair of bracket passage holes 13 of the mounting flange 11 of the mounting bracket 10, is aligned with more than one pair of block passage holes 1012/2012 of the waterblock set 101/201 and receiving portions of the substrate or electronic component (not shown) and configured to correspond to the pair of alignment prongs 22 protruding outwardly from the two opposing diagonal corners of the mounting surface 15 of the housing 24 of the at least one universal fastener assembly 20. Thus, while fastening alignment of holes of liquid-cooling heat exchange apparatus 1/3 may be different, the at least one universal fastener assembly 20 may still be orthogonally assembled through one of the at least two sub-passage holes 131 of the pair of bracket passage holes 13 of the mounting bracket 10, through the pair of block passage holes 1012/2012 and the waterblock leg cutout 111 of the waterblock set 101/102 of the liquid-cooling heat exchange apparatus 1/3, and through the receiving portions of the substrate or electronic component for mounting of the liquid-cooling heat exchange apparatus 1/3 to, as examples, a CPU or GPU mounted to a substrate or electronic component. The mounting bracket 10 is configured to mount liquid-cooling heat exchange apparatuses 1/3 having different fastening alignment of holes for mounting to substrates or electronic components, expanding choices for changing of the liquid cooling apparatus or substrate or electronic component which result in different fastening alignment of holes for mounting.

The universal mounting mechanism of the embodiments may be sized or shaped to mount different types of liquid cooling apparatuses having various sizes, shapes, and base plate thicknesses to different types of CPU or GPU set-ups on a motherboard also having various sizes, shapes, and fastener length requirements due to, as an example, different substrate or set-up thicknesses. Thus, expanding the amount and variety of liquid cooling apparatuses which can be mounted to CPU or GPU set-ups on a motherboard due to the various sizes, shapes, and thicknesses. The liquid cooling apparatuses may be quickly, efficiently, and securely fixed to the substrate or electronic component via the universal mounting mechanism of the embodiments, assuring heat transfer efficiency, and CPU or GPU operation of the electronic component system.

Therefore, embodiments disclosed herein are well adapted to attain the ends and advantages mentioned as well as those that are inherent therein. The particular embodiments disclosed above are illustrative only, as the embodiments disclosed may be modified and practiced in different but equivalent manners apparent to those of ordinary skill in the relevant art having the benefit of the teachings herein. Furthermore, no limitations are intended to the details of construction or design herein shown, other than as described in the claims below. It is therefore evident that the particular illustrative embodiments disclosed above may be altered, combined, or modified and all such variations are considered within the scope and spirit of the present disclosure. The embodiments illustratively disclosed herein suitably may be practiced in the absence of any element that is not specifically disclosed herein and/or any optional element disclosed herein. While compositions and methods are described in terms of “comprising,” “containing,” or “including” various components or steps, the compositions and methods can also “consist essentially of” or “consist of” the various components and steps. All numbers and ranges disclosed above may vary by some amount. Whenever a numerical range with a lower limit and an upper limit is disclosed, any number and any included range falling within the range is specifically disclosed. In particular, every range of values (of the form, “from about a to about b,” or, equivalently, “from approximately a to b,” or, equivalently, “from approximately a-b”) disclosed herein is to be understood to set forth every number and range encompassed within the broader range of values. Also, the terms in the claims have their plain, ordinary meaning unless otherwise explicitly and clearly defined by the patentee. Moreover, the indefinite articles “a” or “an,” as used in the claims, are defined herein to mean one or more than one of the element that it introduces.

What is claimed is:

1. A universal mounting mechanism, configured to mount a liquid-cooling heat exchange apparatus to a substrate or an electronic component, comprising:
a mounting bracket, configured for mounting the liquid-cooling heat exchange apparatus to the substrate or the electronic component, the mounting bracket including a mounting flange having an attachment surface and a mounting surface opposite the attachment surface; and
at least one universal fastener assembly, orthogonally assembled through the mounting bracket from the attachment surface, having a mounted position and a fastened position,
wherein the liquid-cooling heat exchange apparatus includes a first liquid-cooling heat exchange apparatus having a first waterblock set comprising a first block thickness or a second liquid-cooling heat exchange apparatus having a second waterblock set comprising a second block thickness, wherein a thickness of the second block thickness is greater than a thickness of the first block thickness, and
wherein the substrate or the electronic component includes receiving portions having a fastened thickness,
whereby when the at least one universal fastener assembly is assembled and in the fastened position, the at least one universal fastener assembly fastens the first liquid-cooling heat exchange apparatus to the substrate or the electronic component, or the at least one universal fastener assembly fastens the second liquid-cooling heat exchange apparatus to the substrate or the electronic component, whereby a thickness of the second block thickness and the fastened thickness is greater than a thickness of the first block thickness and the fastened thickness.

2. The universal mounting mechanism of claim 1, wherein the at least one universal fastener assembly comprises a fastening clip including a fastening leg having an extended portion and a fastening portion connected to the extended portion, the fastening portion comprising a plurality of contact tension points, whereby when the at least one universal fastener assembly is assembled and in the fastened position, the at least one of the plurality of contact tension points contact the substrate or the electronic component receiving the first liquid-cooling heat exchange apparatus, or the at least one of the plurality of contact tension points contact the substrate or the electronic component receiving the second liquid-cooling heat exchange apparatus, whereby tension contact surface points of the plurality of contact tension points are different tension contact surface points, the different tension contact surface points separated by a distance.

3. The universal mounting mechanism of claim 2, wherein the fastening portion further comprises a buttress portion connected to the fastening portion and extended therefrom, the buttress portion parallel to the bottom plane of the surface of the waterblock set and substrate or the electronic component, whereby when the at least one universal fastener assembly is assembled and in the fastened position, and the buttress portion contacts the substrate or the electronic component receiving the first liquid-cooling heat exchange apparatus, or the buttress portion contacts the substrate or the electronic component receiving the second liquid-cooling heat exchange apparatus, a tension contact surface area of the buttress portion is greater than a surface area of the tension contact surface points of the plurality of contact tension points, increasing friction surface area.

4. The universal mounting mechanism of claim 3, wherein the fastening clip further comprises a handle, an attachment portion and a rotating portion, the rotating portion connected to the extended portion of the fastening leg opposite the buttress portion, the rotating portion parallel to a plane of the attachment surface, the handle connected to the rotating portion opposite the extended portion, the handle defining a finger catch, and the attachment portion connected to the handle opposite the rotating portion, whereby when the at least one universal fastener assembly is assembled and in the mounted position, the handle is in a ready position and rotatable, and when the at least one universal fastener assembly is assembled and in the fastened position, the handle is in a rotated position, whereby when the handle rotates from the ready position to the rotated position, the fastening leg is rotated, whereby the attachment portion rotates on a first axis and the rotating portion rotates on a second axis different from the first axis.

5. The universal mounting mechanism of claim 4, wherein the at least one universal fastener assembly further comprises a housing including an anchor structure, and the mounting bracket further comprises a pair of vertical flanges extending outwardly from opposing longitudinal edges of the mounting flange, the anchor structure mounted furthest away and parallel to at least one of the pair of vertical flanges, whereby when the at least one universal fastener assembly is assembled and in the mounted position, the attachment portion is rotatable within the anchor structure and the rotating portion is rotatable within the anchor structure, and when the handle rotates from the ready position to the rotated position, the fastening leg is rotated, whereby the attachment portion rotates on the first axis within the anchor structure and the rotating portion rotates on the second axis within the anchor structure.

6. The universal mounting mechanism of claim 5, wherein the housing further comprises a mounting surface having four opposing corners, and the at least one universal fastener assembly comprises a pair of alignment prongs protruding outwardly from the mounting surface, each of the pair of alignment prongs including a proximal portion, a distal portion, and at least one tightening rail, the proximal portion protruding outwardly from the mounting surface, the at least one tightening rail protruding longitudinally along the proximal portion, and the distal portion connected to the proximal portion, and a diameter of the proximal portion is greater than a diameter of the distal portion, whereby the fastening leg protrudes outwardly from one corner of the anchor structure via a bracket leg cutout of the mounting flange and a waterblock leg cutout of the waterblock set, and the pair of alignment prongs protrude outwardly from two opposing diagonal corners nearest to the one corner of the anchor structure via a pair of bracket passage holes of the mounting flange and a pair of block passage holes of the waterblock set, each of the pair of bracket passage holes and each of the pair of block passage holes correspond to the pair of alignment prongs, and whereby the pair of alignment prongs protruding outwardly from the two opposing diagonal corners, each having at least one tightening rail, and the corresponding pair of bracket passage holes and the corresponding pair of block passage holes, are configured to laterally fix the at least one universal fastener assembly orthogonally assembled through the mounting bracket.

7. The universal mounting mechanism of claim 6, wherein of the first waterblock set further comprises a pair of first block passage holes and the second waterblock set further comprises a pair of second block passage holes, and wherein each of the pair of bracket passage holes comprise at least two sub-passage holes in communication thereamong and separated by a distance, whereby one of the at least two sub-passage holes is configured to correspond to the pair of alignment prongs protruding outwardly from the two opposing diagonal corners of the mounting surface of the housing and aligned with the pair of first block passage holes and another of the at least two sub-passage holes is configured to correspond to the pair of alignment prongs protruding outwardly from the two opposing diagonal corners of the mounting surface of the housing and aligned with the pair of second block passage holes.

8. The universal mounting mechanism of claim 1, wherein the amount of the at least one universal fastener assembly comprises four, and a shape of the mounting flange of the mounting bracket is quadrilateral shaped, whereby each of the four at least one universal fastener assembly is orthogonally assembled through the mounting bracket from the attachment surface at each of the four corners of the quadrilateral shaped mounting bracket.

9. The universal mounting mechanism of claim 1, wherein the liquid-cooling heat exchange apparatus further comprises a liquid pump module disposed on the waterblock set, controlling the liquid-cooling heat exchange apparatus, the liquid pump module including an inlet and an outlet, and the waterblock set further comprises a heat exchange chamber and a surface, wherein the surface is configured to dissipate heat from heat generating sources, whereby via the inlet and outlet, the liquid pump module circulates fluid within the heat exchange chamber for cooling the heat generating sources.

10. A liquid-cooling heat exchange apparatus, comprising:
a universal mounting mechanism, configured to mount a liquid-cooling heat exchange apparatus to a substrate or an electronic component, comprising:
a mounting bracket, configured for mounting the liquid-cooling heat exchange apparatus to the substrate or the electronic component, the mounting bracket including a mounting flange having an attachment surface and a mounting surface opposite the attachment surface; and
at least one universal fastener assembly, orthogonally assembled through the mounting bracket from the attachment surface, having a mounted position and a fastened position,
wherein the liquid-cooling heat exchange apparatus includes a first liquid-cooling heat exchange apparatus having a first waterblock set comprising a first block thickness or a second liquid-cooling heat exchange apparatus having a second waterblock set comprising a second block thickness, wherein a thickness of the second block thickness is greater than a thickness of the first block thickness, and
wherein the substrate or the electronic component includes receiving portions having a fastened thickness,
whereby when the at least one universal fastener assembly is assembled and in the fastened position, the at least one universal fastener assembly fastens the first liquid-cooling heat exchange apparatus to the substrate or the electronic component, or the at least one universal fastener assembly fastens the second liquid-cooling heat exchange apparatus to the substrate or the electronic component, whereby a thickness of the second block thickness and the fastened thickness is greater than a thickness of the first block thickness and the fastened thickness.

11. The universal mounting mechanism of claim 10, wherein the at least one universal fastener assembly comprises a fastening clip including a fastening leg having an extended portion and a fastening portion connected to the extended portion, the fastening portion comprising a plurality of contact tension points, whereby when the at least one universal fastener assembly is assembled and in the fastened position, the at least one of the plurality of contact tension points contact the substrate or the electronic component receiving the first liquid-cooling heat exchange apparatus, or the at least one of the plurality of contact tension points contact the substrate or the electronic component receiving the second liquid-cooling heat exchange apparatus, whereby tension contact surface points of the plurality of contact tension points are different tension contact surface points, the different tension contact surface points separated by a distance.

12. The universal mounting mechanism of claim 11, wherein the fastening portion further comprises a buttress portion connected to the fastening portion and extended therefrom, the buttress portion parallel to the bottom plane of the surface of the waterblock set and substrate or the electronic component, whereby when the at least one universal fastener assembly is assembled and in the fastened position, and the buttress portion contacts the substrate or the electronic component receiving the first liquid-cooling heat exchange apparatus, or the buttress portion contacts the substrate or the electronic component receiving the second liquid-cooling heat exchange apparatus, a tension contact surface area of the buttress portion is greater than a surface area of the tension contact surface points of the plurality of contact tension points, increasing friction surface area.

13. The universal mounting mechanism of claim 12, wherein the fastening clip further comprises a handle, an attachment portion and a rotating portion, the rotating portion connected to the extended portion of the fastening leg opposite the buttress portion, the rotating portion parallel to a plane of the attachment surface, the handle connected to the rotating portion opposite the extended portion, the handle defining a finger catch, and the attachment portion connected to the handle opposite the rotating portion, whereby when the at least one universal fastener assembly is assembled and in the mounted position, the handle is in a ready position and rotatable, and when the at least one universal fastener assembly is assembled and in the fastened position, the handle is in a rotated position, whereby when the handle rotates from the ready position to the rotated position, the fastening leg is rotated, whereby the attachment portion rotates on a first axis and the rotating portion rotates on a second axis different from the first axis.

14. The universal mounting mechanism of claim 13, wherein the at least one universal fastener assembly further comprises a housing including an anchor structure, and the mounting bracket further comprises a pair of vertical flanges extending outwardly from opposing longitudinal edges of the mounting flange, the anchor structure mounted furthest away and parallel to at least one of the pair of vertical flanges, whereby when the at least one universal fastener assembly is assembled and in the mounted position, the attachment portion is rotatable within the anchor structure and the rotating portion is rotatable within the anchor structure, and when the handle rotates from the ready position to the rotated position, the fastening leg is rotated, whereby the attachment portion rotates on the first axis within the anchor structure and the rotating portion rotates on the second axis within the anchor structure.

15. The universal mounting mechanism of claim 14, wherein the housing further comprises a mounting surface having four opposing corners, and the at least one universal fastener assembly comprises a pair of alignment prongs protruding outwardly from the mounting surface, each of the pair of alignment prongs including a proximal portion, a distal portion, and at least one tightening rail, the proximal portion protruding outwardly from the mounting surface, the at least one tightening rail protruding longitudinally along the proximal portion, and the distal portion connected to the proximal portion, and a diameter of the proximal portion is greater than a diameter of the distal portion, whereby the fastening leg protrudes outwardly from one corner of the anchor structure via a bracket leg cutout of the mounting flange and a waterblock leg cutout of the waterblock set, and the pair of alignment prongs protrude outwardly from two opposing diagonal corners nearest to the one corner of the anchor structure via a pair of bracket passage holes of the mounting flange and a pair of block passage holes of the waterblock set, each of the pair of bracket passage holes and each of the pair of block passage holes correspond to the pair of alignment prongs, and whereby the pair of alignment prongs protruding outwardly from the two opposing diagonal corners, each having at least one tightening rail, and the corresponding pair of bracket passage holes and the corresponding pair of block passage holes, are configured to laterally fix the at least one universal fastener assembly orthogonally assembled through the mounting bracket.

16. The universal mounting mechanism of claim 15, wherein of the first waterblock set further comprises a pair of first block passage holes and the second waterblock set further comprises a pair of second block passage holes, and wherein each of the pair of bracket passage holes comprise at least two sub-passage holes in communication thereamong and separated by a distance, whereby one of the at least two sub-passage holes is configured to correspond to the pair of alignment prongs protruding outwardly from the two opposing diagonal corners of the mounting surface of the housing and aligned with the pair of first block passage holes and another of the at least two sub-passage holes is configured to correspond to the pair of alignment prongs protruding outwardly from the two opposing diagonal corners of the mounting surface of the housing and aligned with the pair of second block passage holes.

17. The universal mounting mechanism of claim 10, wherein the amount of the at least one universal fastener assembly comprises four, and a shape of the mounting flange of the mounting bracket is quadrilateral shaped, whereby each of the four at least one universal fastener assembly is orthogonally assembled through the mounting bracket from the attachment surface at each of the four corners of the quadrilateral shaped mounting bracket.

18. The universal mounting mechanism of claim 10, wherein the liquid-cooling heat exchange apparatus further comprises a liquid pump module disposed on the waterblock set, controlling the liquid-cooling heat exchange apparatus, the liquid pump module including an inlet and an outlet, and the waterblock set further comprises a heat exchange chamber and a surface, wherein the surface is configured to dissipate heat from heat generating sources, whereby via the inlet and outlet, the liquid pump module circulates fluid within the heat exchange chamber for cooling the heat generating sources.
